(19) United States
(12) Patent Application Publication
(10) Pub. No.: US 2019/0094618 A1
(43) Pub. Date: Mar. 28, 2019

(54) LIGHTING DEVICE AND DISPLAY DEVICE PROVIDED WITH THE SAME

(71) Applicant: SHARP KABUSHIKI KAISHA, Osaka (JP)

(72) Inventors: YOUZOU KYOUKANE, Sakai City (JP); HISASHI WATANABE, Sakai City (JP); HIROTOSHI YASUNAGA, Sakai City (JP)

(21) Appl. No.: 16/147,397

(22) Filed: Sep. 28, 2018

(30) Foreign Application Priority Data
Sep. 28, 2017 (JP) 2017-187726

(51) Int. Cl. G02F 1/1335

(52) U.S. Cl. CPC G02F 1/133603; H01L 25/0753; G02F 1/133606; G02F 1/133605

(57) ABSTRACT

A lighting device includes a board on which a plurality of light emitting devices are arranged in a matrix, and a reflection sheet provided on the board and having a plurality of apertures. The apertures correspond one-to-one to the light emitting devices. The reflection sheet is extended in a predetermined specific extending direction. The apertures are formed such that a first distance in the extending direction between rims of the apertures and side surfaces of the corresponding light emitting devices within the apertures is greater than a second distance in an orthogonal direction that is orthogonal to the extending direction between the rims of the apertures and the side surfaces of the corresponding light emitting devices.

### CROSS-REFERENCE TO RELATED APPLICATIONS

The present application claims priority under 35 U.S.C. § 119(a) to Japanese Patent Application No. 2017-187726, filed on Sep. 28, 2017, the contents of which are incorporated herein by reference in its entirety.

### BACKGROUND OF THE INVENTION

### Field of the Invention

The present invention relates to a lighting device such as a backlighting device, and a display device provided with the same.

### Related Art

Lighting devices such as a backlighting device typically include the edge-lit type devices and the direct-lit type devices. In the edge-lit type device, a light guiding panel is provided behind a slim display device such as a liquid crystal panel, and a plurality of light emitting devices such as light emitting diodes (LED) are arranged along the edge of the light guiding panel. Light is emitted from the light emitting devices through the light guiding panel and illuminates the slim display device entirely and uniformly. In the direct-lit type device, a plurality of light emitting devices are arranged behind a display device. Light is emitted from the light emitting devices behind the display device and illuminates the display device entirely and uniformly. The edge-lit lighting device can decrease its thickness by making the light guiding panel thinner, but the thinner structure deteriorates the image quality in terms of luminance, contrast, etc.

The direct-lit lighting device is mainly utilized for products which seek for high luminance and high contrast, such as televisions and digital signage devices, by controlling the amount of light emitted from the light emitting devices individually or zone by zone (known as local dimming control). Recently, use of the direct-lit lighting devices has extended to in-vehicle compact display devices which operate under a wide range of temperature environments.

The direct-lit lighting devices can improve the image quality in terms of luminance, contrast, etc. by local dimming control. To operate under a specific high-temperature environment, however, the direct-lit lighting devices have to cope with the following problem.

FIGS. 14 to 21 are illustrations for describing the problem in using a conventional direct-lit lighting device 5 under a specific high-temperature environment. FIG. 14 is a schematic sectional view of the conventional direct-lit lighting device 5. FIG. 15 is a schematic sectional view of the lighting device 5 shown in FIG. 14, showing how light L is diffused by a diffuser panel 6 and a reflection sheet 4. FIG. 16 is a schematic perspective view showing an example in which the reflection sheet 4 is provided on a board 2 on which a plurality of light emitting devices 1-1 are arranged in a matrix. FIG. 17 is a schematic sectional view showing a distance D between rims 3a of apertures 3-3 in the reflection sheet 4 and the light emitting devices 1-1. FIG. 18 is a schematic sectional view showing the positional relationship between the aperture 3 and the reflection sheet 4 in the initial state. FIG. 19 shows a luminance distribution of the lighting device 5 in the initial state. FIG. 20 is a schematic sectional view showing the positional relationship between the aperture 3 and the reflection sheet 4 after the lighting device is left under a high-temperature environment. FIG. 21 shows a luminance distribution of the lighting device 5 after the lighting device is left under a high-temperature environment. In FIGS. 18 and 20, the diffuser panel 6 is omitted. In FIGS. 19 and 21, a lower density means a lower luminance.

As shown in FIGS. 14 to 16, the conventional direct-lit lighting device 5 includes a board 2 on which a plurality of light emitting devices 1-1 such as LEDs are arranged in a matrix, and a reflection sheet 4 provided on a mount surface of the board 2 on which the light emitting devices 1 are mounted. The reflection sheet 4 has a plurality of apertures 3-3 for individually exposing the light emitting devices 1-1. The lighting device 5 also includes a diffuser panel 6 opposed to the mount surface of the board 2 on which the light emitting devices 1 are mounted. A white resist 2a (specifically, white ink) is applied to the board 2. For more efficient use of the light L, the reflection sheet 4 is provided on the board 2 coated with the white resist 2a. The reflection sheet 4 has a white reflection surface 4a which shows excellent reflectivity for the light L. The diffuser panel 6 has a function of diffusing the light L from the light emitting devices 1-1, the white resist 2a, and the reflection sheet 4.

In the lighting device 5, the light L reflected by the diffuser panel 6 is reflected in both a first reflection region a where the white resist 2a on the board 2 is exposed and a second reflection region β on the reflection sheet 4, as shown in FIG. 17. The optical reflectance in the first reflection region α is typically between about 70% to 80% because the white resist 2a cannot be made any thicker. On the other hand, the optical reflectance in the second reflection region β is typically about 95% or higher because the reflection sheet 4 can be made thicker. Hence, if the dimension of the first reflection region α is smaller, namely, if the distance D between the rim 3a (an inner peripheral surface) of each aperture 3 in the reflection sheet 4 and a side surface 1b (an outer peripheral surface) of each light emitting device 1 within the aperture 3 is smaller, the second reflection region β having an optical reflectance of 95% or higher has a greater area. This arrangement ensures advantageous optical characteristics for efficient use of the light L. The distance D is set in advance as tolerance, in consideration of variations such as a variation in size of the light emitting devices 1-1, a variation in forming the apertures 3-3 in the reflection sheet 4, a variation in mounting the light emitting devices 1-1 on the board 2, and a variation in attaching the reflection sheet 4 to the board 2.

In general, a reflection sheet for use in a lighting device is extended during manufacture in a predetermined specific extending direction.

Depending on the environment of application and use, the lighting device 5 needs to adapt to a wider operable temperature range under a lower and/or higher temperature environment than in the case of televisions and digital signage devices. In particular, for in-vehicle application and use, it is necessary to suppose, for example, a durable temperature range of −40° C. to 95° C.

For example, in the initial state of the lighting device 5 as shown in FIG. 18, the reflection sheet 4 allows unobstructed emission of light L from the light emitting devices 1-1. The lighting device 5 can provide uniform lighting as shown in FIG. 19, for example, at a luminance uniformity of 90% and substantially without non-uniformity in luminance. In this context, luminance uniformity is a ratio of the minimum luminance to the maximum luminance at a plurality of locations.

On the other hand, if the lighting device 5 is left under a specific high-temperature environment (e.g. under an environment at about 95° C.), the reflection sheet 4 which has been extended in a extending direction E thermally shrinks in the extending direction E, and may cover a light emitting surface 1a of the light emitting device 1 not in contact with the board 2, as shown in FIG. 20. In this case, the reflection sheet 4 obstructs outgoing light La from the light emitting surface 1a of the light emitting device 1, darkens the obstructed part, and causes non-uniformity in luminance. The resulting lighting device 5 has a luminance uniformity of as low as 68%, fails to provide uniform illumination as shown in FIG. 21, and eventually degrades the display quality of the display device.

The light emitting device 1 can emit light with wider directional characteristics in light emission, by emitting light L not only from the light emitting surface 1a but also from the side surface 1b around the light emitting surface 1a. In the initial state as shown in FIGS. 18 and 19, such a light emitting device can disperse the light L better and can provide illumination with enhanced uniformity, thereby enhancing the display quality of the display device. However, as shown in FIGS. 20 and 21, after the lighting device is left under a high-temperature environment, the heat-shrunk reflection sheet 4 covers the light emitting surface 1a of the light emitting device 1 and obstructs the light L not only from the light emitting surface 1a of the light emitting device 1 but also from the side surface 1b of the light emitting device 1. Even if not covering, if the heat-shrunk reflection sheet 4 comes into contact with or in proximity to the side surface 1b of the light emitting device 1, the reflection sheet 4 obstructs the light L from the side surface 1b of the light emitting device 1, darkens the obstructed part, and causes non-uniformity in luminance.

In this respect, JP 2013-118117 A suggests a lighting device in which cuts are provided around the apertures in the reflection sheet.

However, the lighting device disclosed in JP 2013-118117 A intends to avoid deflection in the reflection sheet due to thermal expansion by providing the cuts. According to this structure, if a reflection sheet extended in a extending direction thermally shrinks in the extending direction, heat shrinkage occurs all over the reflection sheet irrespective of the cuts around the apertures in the reflection sheet. Eventually, the heat-shrunk reflection sheet covers the light emitting surface of the light emitting device, or comes into contact with or in proximity to the side surface of the light emitting device, and still causes non-uniformity in luminance.

In view of the above-mentioned problem, the present invention aims to provide a lighting device which can effectively prevent non-uniformity in luminance and can thereby provide uniform illumination even when a reflection sheet thermally shrinks under a specific high-temperature environment, and also to provide a display device provided with the lighting device.

### SUMMARY OF THE INVENTION

In order to achieve the above-mentioned object, a lighting device according to an embodiment of the present invention includes a board on which a plurality of light emitting devices are arranged in a matrix, and a reflection sheet provided on the board and having a plurality of apertures, the apertures corresponding one-to-one to the light emitting devices. In this lighting device, the reflection sheet is extended in a predetermined specific extending direction. The apertures are formed such that a first distance in the extending direction between rims of the apertures and side surfaces of the corresponding light emitting devices within the apertures is greater than a second distance in an orthogonal direction that is orthogonal to the extending direction between the rims of the apertures and the side surfaces of the corresponding light emitting devices. A display device according to an embodiment of the present invention is provided with the lighting device according to the above-mentioned embodiment of the present invention.

The present invention can effectively prevent non-uniformity in luminance and can thereby provide uniform illumination even when a reflection sheet thermally shrinks under a specific high-temperature environment.

### BRIEF DESCRIPTION OF THE DRAWINGS

FIG. 1 is a partial schematic sectional view of a liquid crystal display equipped with a backlighting device according to the first embodiment.

FIG. 2 is a schematic plan view of the backlighting device shown in FIG. 1, with an optical element group and a diffuser panel removed.

FIG. 3 is an enlarged partial schematic plan view of a reflection sheet shown in FIGS. 1 and 2.

FIG. 4 is a schematic plan view of apertures in the reflection sheet, the aperture on the left being formed too large and the aperture on the right being formed according to the first embodiment.

FIG. 5 is an enlarged schematic plan view of an aperture in the reflection sheet according to the first embodiment.

FIG. 6 is a schematic plan view showing an example of an LED on an LED board, in which the longitudinal direction of the LED is aligned with a extending direction.

FIG. 7 is a schematic plan view showing another example of the LED on the LED board, in which the longitudinal direction of the LED is aligned with an orthogonal direction that is orthogonal to the extending direction.

FIG. 8 is a schematic plan view showing a different example of the LED in a backlighting device according to the second embodiment.

FIG. 9 is a schematic plan view showing an example of a backlighting device according to the third embodiment, in which the reflection sheet is divided in a plurality of pieces.

FIG. 10 is a schematic perspective view of the backlighting device according to the third embodiment, in which adjacent ends of the divided reflection sheets are overlapped.

FIG. 11 is a schematic sectional view of a configuration example, in which a specific pattern is printed in ink on a surface of a diffuser panel opposed to the LED board.

FIG. 12 is a schematic sectional view of a configuration example, in which a reflection panel having apertures in a specific pattern is provided on the surface of the diffuser panel opposed to the LED board.

FIG. 13 is a schematic plan view showing an example of the specific pattern shown in FIGS. 11 and 12.

FIG. 14 is a schematic sectional view of a conventional direct-lit lighting device.

FIG. 15 is a schematic sectional view of the lighting device shown in FIG. 14, showing how light is diffused by a diffuser panel and a reflection sheet.

FIG. 16 is a schematic perspective view showing an example in which the reflection sheet is provided on a board on which a plurality of light emitting devices are arranged in a matrix.

FIG. 17 is a schematic sectional view showing a distance between rims of apertures and the light emitting devices in the reflection sheet.

FIG. 18 is a schematic sectional view showing the positional relationship between the aperture and the reflection sheet in the initial state.

FIG. 19 shows a luminance distribution of the lighting device in the initial state.

FIG. 20 is a schematic sectional view showing the positional relationship between the aperture and the reflection sheet after the lighting device is left under a high-temperature environment.

FIG. 21 shows a luminance distribution of the lighting device after the lighting device is left under a high-temperature environment.

### DESCRIPTION OF PREFERRED EMBODIMENTS

Hereinafter, the embodiments according to the present invention are described with reference to the drawings. In the following description, the same components having the same appellations and functions are indicated by the same reference numerals. By using the same reference numerals, detailed description of such components is omitted.

### First Embodiment

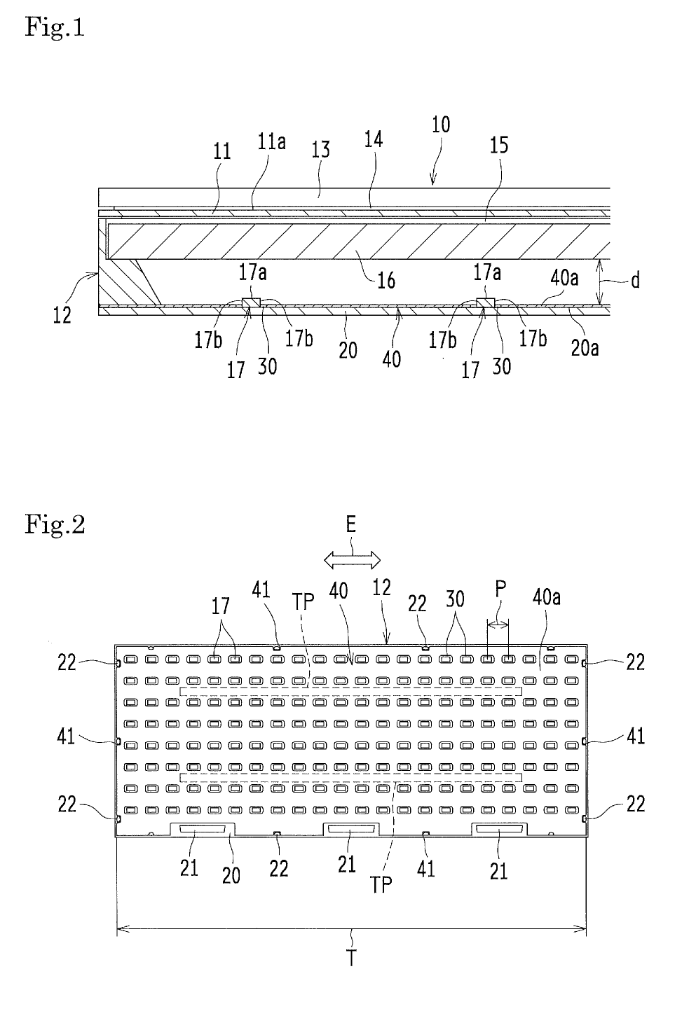

FIG. 1 is a partial schematic sectional view of a liquid crystal display 10 equipped with a backlighting device 12 according to the first embodiment. FIG. 2 is a schematic plan view of the backlighting device 12 shown in FIG. 1, with an optical element group 15 and a diffuser panel 16 removed.

As shown in FIG. 1, a liquid crystal display (an example of the display device) 10 has a landscape-oriented rectangular shape as a whole and is placed in a horizontal orientation in use. In this example, the liquid crystal display 10 has a 12.3-inch display screen for in-vehicle application and use. The liquid crystal display 10 is provided with a liquid crystal panel 11 and a backlighting device (an example of the lighting device) 12 for illuminating the liquid crystal panel 11 from behind. The shape of the liquid crystal display 10 is not particularly limited and may also be a square.

The liquid crystal panel 11, details of which are omitted in the drawings, is composed of a pair of glass substrates bonded together with a specific gap, and liquid crystal encapsulated between the glass substrates.

The backlighting device 12, being the direct-lit type, is disposed on the opposite side of a display surface 11a of the liquid crystal panel 11. The backlighting device 12 is provided with an optical element group 15, a diffuser panel 16, a reflection sheet 40, and an LED board (an example of the board) 20. The optical element group 15 is a laminate of a plurality of optical sheets thinner than the diffuser panel 16, and is arranged between the liquid crystal panel 11 and the diffuser panel 16. The optical element group 15 has a function of changing light passing through the diffuser panel 16 to planar light. The optical element group 15 is typically composed of, although not shown, a brightness enhancement film and a prism sheet. The diffuser panel 16 is composed of a plate-like synthetic resin member and light scattering particles dispersed therein, and has a light diffusing function.

An LED board 20 is coated with a white resist 20a (specifically, white ink). On the LED board 20 coated with the white resist 20a, a plurality of light emitting diodes 17-17 (an example of light emitting devices, hereinafter called LEDs 17-17) which emit white light are arranged in a matrix at a predetermined specific identical pitch P (about 13 mm in this example) (see FIG. 2). The LEDs 17-17 emit light from light emitting surfaces 17a which are not in contact with the LED board 20. In this example, the LEDs 17-17 are so-called top-view light emitting LEDs. Each LED 17 is provided in a transparent resin package so as to emit light also from a side surface 17b and to ensure wide directional characteristics in light emission. Owing to this structure, the LEDs 17-17 can emit light not only from the light emitting surfaces 17a but also from the side surfaces 17b around the light emitting surfaces 17a. The LEDs 17-17 are chip LEDs mounted on an LED board 20 such as a rigid board (e.g. a board made of a metallic material such as aluminium and having rigidity) or a flexible printed board (e.g. a board made of a resin material such as polyimide and having flexibility). The LED board 20 is electrically connected to a power source unit (not shown) controlled by a power source control unit (not shown), via connectors 21-21. A specific voltage is applied from the power source unit and lights up the LEDs 17-17. The power source control unit provides local dimming control to the power source unit. The thus configured and controlled backlighting device 12 can illuminate the liquid crystal panel 11 at high luminance and high contrast. All of the LEDs 17-17 are made in the same shape (the same specification). Typically, the shape of the LEDs 17-17 in plan view (the shape of the light emitting surfaces 17a) may be rectangular, square, elliptical, or circular.

The diffuser panel 16 is provided at a predetermined specific clearance d (about 4 mm in this example), in an opposed manner to a mount surface of the LED board 20 on which the LEDs 17 are mounted. Materials for the diffuser panel 16 include heat-resistant resin materials such as polycarbonate resins and acrylic resins. In this example, the diffuser panel 16 is made of a polycarbonate resin. The clearance d between the diffuser panel 16 and the LED board 20 can be determined, for example, depending on a pitch P between the LEDs 17, 17.

The liquid crystal display 10 further has a transparent protective member 13 provided on the liquid crystal panel 11. The transparent protective member 13 is adhered to the liquid crystal panel 11 via a transparent adhesive member 14 such as a functional film (OCA, Optical Clear Adhesive, film). The transparent protective member 13 may be configured by cover glass or a touch panel, and has a function of protecting the display surface 11a of the liquid crystal panel 11.

(Reflection Sheet)

Next, a reflection sheet 40 is described in detail. The reflection sheet 40 has a white reflection surface 40a having excellent light reflectivity. The reflection sheet 40 is provided on the LED board 20 (specifically, on the mount surface of the LED board 20 on which the LEDs 17 are mounted). The reflection sheet 40 has a plurality of apertures 30-30. The apertures 30-30 in the reflection sheet 40 correspond to the LEDs 17-17, and expose the corresponding LEDs 17-17 therethrough (allow the corresponding LEDs 17-17 to project therethrough). The apertures 30-30 may be shaped according to the LEDs 17-17, in the same or substantially the same shape as the LEDs 17-17. All of the apertures 30-30 have an identical shape. The reflection sheet 40 is positioned by positioning units 41 (specifically, dents) onto positioning units 22 of the LED board 20 (specifically, bumps). The reflection sheet 40 are attached to the LED board 20 by double-sided adhesive sheets TP-TP at a plurality of locations. Materials for the reflection sheet 40 include, for example, PET (polyethylene terephthalate) resins, PP (polypropylene) resins, PVC (polyvinyl chloride) resins, PC (polycarbonate) resins, PMMA (acrylic) resins, and the like. In this example, the reflection sheet 40 is made of a PET resin. The reflection sheet 40 is extended in a predetermined specific extending direction E during manufacture.

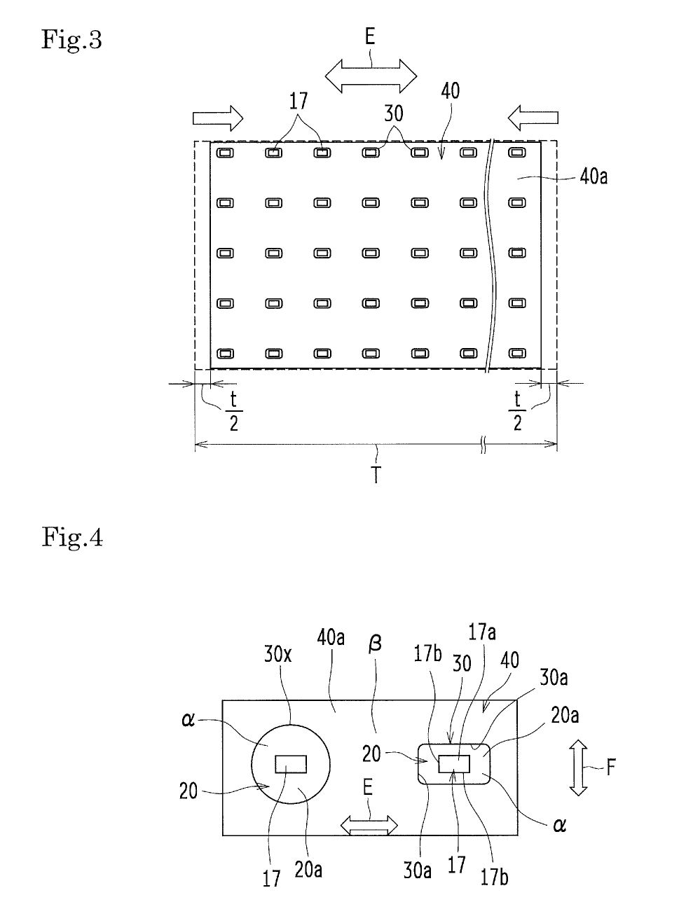

FIG. 3 is an enlarged partial schematic plan view of the reflection sheet 40 shown in FIGS. 1 and 2. Basically, the backlighting device 12 requires heat-resistance in a specific high-temperature environment (e.g. a temperature over 60° C.). The extended reflection sheet 40 thermally shrinks in the extending direction E under a specific high-temperature environment which causes heat shrinkage of the reflection sheet 40. For example, under a high-temperature environment at 95° C., the reflection sheet 40 made of a PET resin shrinks at a heat shrinkage rate p of about 0.4%, in a heat shrinkage amount t of about 1.2 mm relative to the total length T, about 300 mm, of the reflection sheet 40 in the extending direction E. In this context, the heat shrinkage rate p is a ratio of the heat shrinkage amount t of the reflection sheet 40 in the extending direction E relative to the total length T of the reflection sheet 40 in the extending direction E, under a specific high-temperature environment.

Hence, the apertures 30-30 in the reflection sheet 40 require tolerance in consideration of variations such as a variation in size of the LEDs 17-17, a variation in forming the apertures 30-30 in the reflection sheet 40, a variation in mounting the LEDs 17-17 on the LED board 20, and a variation in attaching the reflection sheet 40 to the LED board 20. It is also necessary to consider the heat shrinkage of the reflection sheet 40 in the extending direction E.

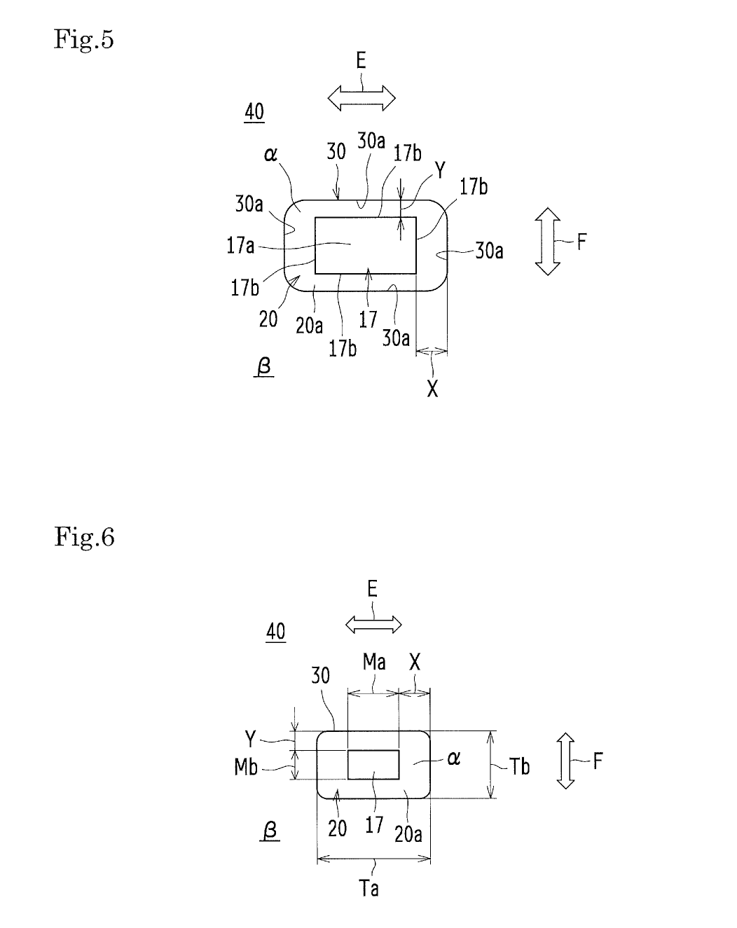

FIG. 4 is a schematic plan view of apertures in the reflection sheet 40, an aperture 30x on the left being formed too large and an aperture 30 on the right being formed according to the first embodiment. FIG. 5 is an enlarged schematic plan view of an aperture 30 in the reflection sheet 40 according to the first embodiment.

In FIG. 4, the aperture 30x on the left is formed in the reflection sheet 40 in consideration of the tolerance and the heat shrinkage, but is too large. This aperture 30x reduces the area of the second reflection region β on the reflection sheet 40 (increases the area of the first reflection region α where the white resist 20a on the LED board 20 is exposed), and results in less efficient use of light. Typically, the optical reflectance in the first reflection region α is about 70% to 80%, and the optical reflectance in the second reflection region β is about 95% or higher.

The aperture 30 according to the present embodiment is shown on the right in FIG. 4 and also in FIG. 5. The first distance X represents a distance in the extending direction E, between the rim 30a of the aperture 30 and the side surface 17b of the LED 17 located within the aperture 30. The second distance Y represents a distance in an orthogonal direction F that is orthogonal to the extending direction E, between the rim 30a of the aperture 30 and the side surface 17b of the LED 17 located within the aperture 30. The aperture 30 is formed such that the first distance X is greater than the second distance Y.

According to the present embodiment, even if the reflection sheet 40 thermally shrinks in the extending direction E under a specific high-temperature environment which causes heat shrinkage of the reflection sheet 40, the largeness of the first distance X over the second distance Y can absorb heat shrinkage and can thereby prevent the heat-shrunk reflection sheet 40 from covering the light emitting surface 17a of the LED 17. Hence, despite the heat shrinkage of the reflection sheet 40 under a specific high-temperature environment, the present embodiment can effectively prevent non-uniformity in luminance and can thereby provide uniform illumination. The present embodiment is particularly effective in the case where the LED 17 emits light from both the light emitting surface 17a and the side surface 17b. Besides, the smaller the second distance Y is than the first distance X, the greater the area of the second reflection region β of the reflection sheet 40 can be (the smaller the first reflection region α where the white resist 20a of the LED board 20 is exposed can be). This leads to more efficient use of light.

The extending direction E of the reflection sheet 40 can be checked, for example, by means of an ellipsometer for measuring a change in polarization between the incident light on and the reflected light from the reflection sheet 40. Specifically, considering a phase shift and a difference in optical reflectance between s polarization and p polarization, the change in polarization between the incident light and the reflected light is defined by the phase difference Δ between s polarization and p polarization and the reflection-amplitude ratio Ψ between s polarization and p polarization, and is usually represented as (Ψ, Δ).

As the first distance X, if distances measured at opposed locations in the orthogonal direction F that is orthogonal to the extending direction E are different, the first distance X may be the maximum distance or an average distance of such distances measured at the opposed locations. Similarly, as the second distance Y, if distances measured at opposed locations in the extending direction E are different, the second distance Y may be the maximum distance or an average distance of such distances measured at the opposed locations. The second distance Y may be set in advance as tolerance in consideration of variations such as a variation in size of the LEDs 17-17, a variation in forming the apertures 30-30 in the reflection sheet 40, a variation in mounting the LEDs 17-17 on the LED board 20, and a variation in attaching the reflection sheet 40 to the LED board 20. Examples of the reflection sheet 40 extended in the extending direction E include a reflection sheet manufactured by melting and extrusion molding of a resin base material in the form of powder, granules, pellets, or the like, with extending in the extending direction and cooling being applied during manufacture.

In the present embodiment, the LEDs 17-17 are located at the center in the apertures 30-30. The apertures 30-30 are formed in the reflection sheet 40 to satisfy following Formula 1,

X>Y+t/2 Formula 1

where t represents the amount of heat shrinkage of the reflection sheet 40 under a predetermined specific high-temperature environment.

In other words, the first distance X is greater than the sum of the second distance Y and a half of the heat shrinkage amount t of the reflection sheet 40 in the extending direction E under a specific high-temperature environment. This condition can reliably prevent the heat-shrunk reflection sheet 40 from covering the light emitting surfaces 17a of the LEDs 17-17, or coming into contact with or in proximity to the side surfaces 17b of the LEDs 17-17, under a specific high-temperature environment. In this embodiment, the heat shrinkage amount t (e.g. about 1.2 mm) can be obtained by multiplying the total length T (e.g. 300 mm) of the reflection sheet 40 in the extending direction E, by the heat shrinkage rate p (e.g. about 0.4%) under a specific high-temperature environment.

Incidentally, more efficient use of light can be expected if the first reflection region α where the white resist 20a on the LED board 20 is exposed (the area of the LED board 20 corresponding to the apertures 30 and excluding the LEDs 17) has a smaller area. In the case where the LEDs 17 have a rectangular or elliptical shape (rectangular in this example) elongated in a specific longitudinal direction, as seen in plan view of the LED board 20, the longitudinal direction of the LEDs 17 may be aligned with, for example, the extending direction E or the orthogonal direction F that is orthogonal to the extending direction E.

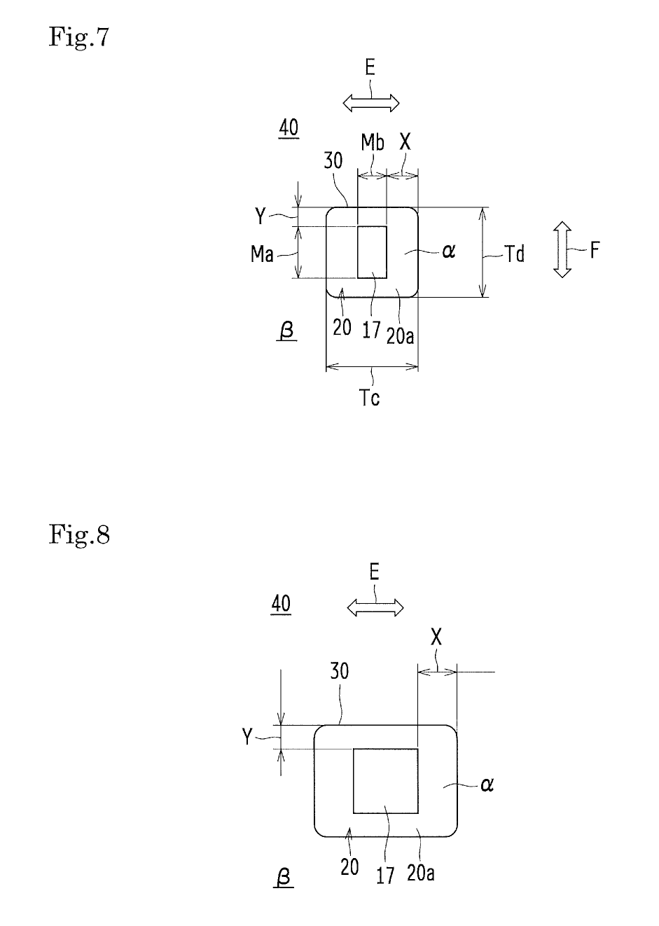

FIG. 6 is a schematic plan view showing an example of the LED 17 on the LED board 20, in which the longitudinal direction of the LED 17 is aligned with the extending direction E. FIG. 7 is a schematic plan view showing another example of the LED 17 on the LED board 20, in which the longitudinal direction of the LED 17 is aligned with the orthogonal direction F that is orthogonal to the extending direction E. The apertures 30 are formed to satisfy the condition X>Y in whichever case, namely, when the longitudinal direction of the LED 17 on the LED board 20 is aligned with the extending direction E as shown in FIG. 6, or when the longitudinal direction of the LED 17 on the LED board 20 is aligned with the orthogonal direction F that is orthogonal to the extending direction E as shown in the FIG. 7.

The area of the aperture 30 shown in FIG. 6 (Ta×Tb) and the area of the aperture 30 shown in FIG. 7 (Tc×Td) have the following relationship, with the proviso that: regarding the LED 17, Ma is the longer dimension, and Mb is the shorter dimension (Ma>Mb); regarding the aperture 30 in FIG. 6, Ta is the dimension in the extending direction E, and Tb is the dimension in the orthogonal direction F; and regarding the aperture 30 shown in FIG. 7, Tc is the dimension in the extending direction E, and Td is the dimension in the orthogonal direction F,

Ta×Tb=(Ma+2X)(Mb+2Y)=MaMb+2YMa+2XMb+4XY

Tc×Td=(Mb+2X)(Ma+2Y)=MaMb+2YMb+2XMa+4XY

(Ta×Tb)−(Tc×Td)=2Y(Ma−Mb)−2X(Ma−Mb)

organize the right-hand side,

(Ta×Tb)−(Tc×Td)=2(Y−X)(Ma−Mb)

wherein (Y−X) is negative because X>Y, and (Ma−Mb) is positive because Ma>Mb, therefore,

(Ta×Tb)−(Tc×Td)<0

(Ta×Tb)<(Tc×Td).

Namely, the area of the aperture shown in FIG. 6 (Ta×Tb) is smaller than the area of the aperture shown in FIG. 7 (Tc×Td). Since the area of the LED 17 (Ma×Mb) are the same in both apertures, the area of the first reflection region α in the aperture shown in FIG. 6, [(Ta×Tb)−(Ma×Mb)], is smaller than the area of the first reflection region α in the aperture shown in FIG. 7, [(Tc×Td)−(Ma×Mb)]. The smaller aperture area leads to more efficient use of light.

As described above, regarding the orientation of the LED 17 provided on the LED board 20, the present embodiment can achieve more efficient use of light in the case where the longitudinal direction of the LED 17 is aligned with the extending direction E as shown in FIG. 6, than in the case where the longitudinal direction of the LED 17 is aligned with the orthogonal direction F as shown in FIG. 7.

### Second Embodiment

FIG. 8 is a schematic plan view showing a different example of the LED 17 in the backlighting device 12 according to the second embodiment. In the backlighting device 12 according to the first embodiment, the LED 17 has a shape elongated in a specific longitudinal direction, as seen in plan view of LED board 20. In the backlighting device 12 according to the second embodiment, the LED 17 has a square or circular shape (a square in this example).

Also in the case where the LED 17 has a square or circular shape, the aperture 30 is formed such that the first distance X is greater than the second distance Y. Similar to the first embodiment, this embodiment can effectively prevent non-uniformity in luminance and can thereby provide uniform illumination despite the heat shrinkage of the reflection sheet 40 under a specific high-temperature environment.

### Third Embodiment

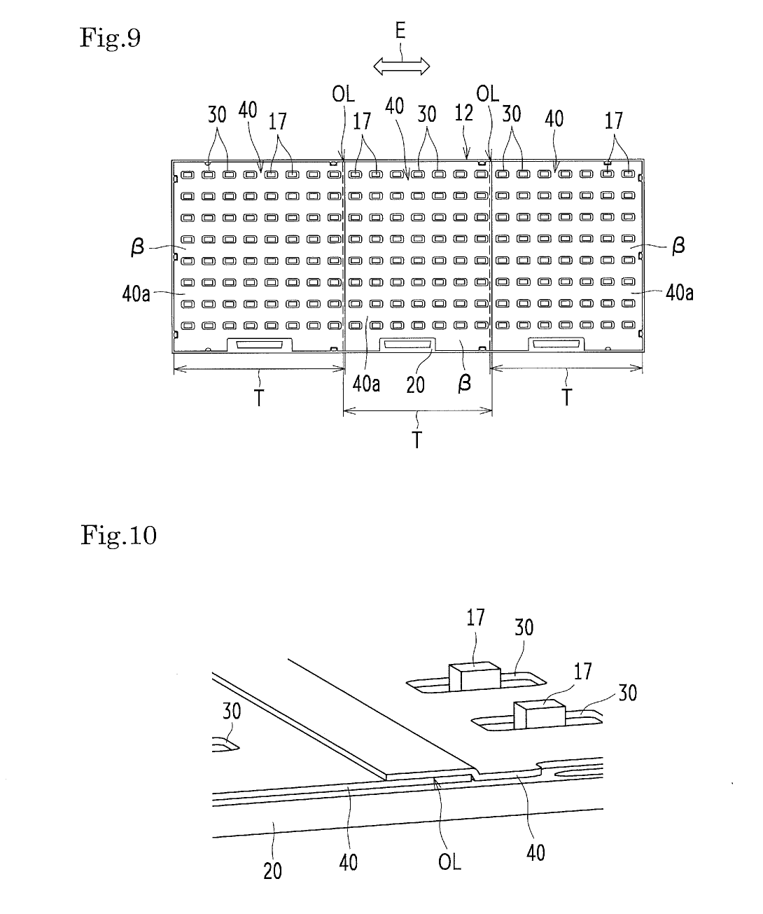

FIG. 9 is a schematic plan view showing an example of the backlighting device 12 according to the third embodiment, in which the reflection sheet 40 is divided in a plurality of pieces.

Basically, the reflection sheet 40 having a greater total length T in the extending direction E shows a greater amount of heat shrinkage (T×μ). The greater amount of heat shrinkage increases the first distance X and decreases the area of the second reflection region β in the reflection sheet 40, which results in less efficient use of light.

As shown in FIG. 9, the present embodiment divides the reflection sheet 40 into a plurality of pieces in the extending direction E (specifically, the reflection sheet 40 is divided along the center between adjacent LEDs 17, 17). This arrangement decreases the total length T, and accordingly decreases the heat shrinkage amount (T×μ). The smaller amount of heat shrinkage decreases the first distance X and increases the area of the second reflection regions B in the divided reflection sheets 40-40, which leads to more efficient use of light.

FIG. 10 is a schematic perspective view of the backlighting device 12 according to the third embodiment, in which adjacent ends of the divided reflection sheets 40-40 are overlapped.

If the divided reflection sheets 40-40 have a gap between adjacent ends thereof, light is reflected by the white resist 20a of the LED board 20 exposed from the gap, which results in less efficient use of light.

In this regard, the present embodiment provides the divided reflection sheets 40-40 on the LED board 20 by overlapping the adjacent ends of the reflection sheets, as shown in FIG. 10. This overlapping arrangement can eliminate a gap between the adjacent ends and can thereby avoid deterioration of efficiency in using light. In this example, overlapped portions OL, OL of each reflection sheet 40 are overlapped in an alternating manner, i.e. the overlapped portion along one end lies under an adjacent reflection sheet and the overlapped portion along the other end lies on top of another adjacent reflection sheet. The arrangement of the overlapped portions OL, OL should not be limited thereto, and the overlapped portions OL, OL of the reflection sheet 40 may both be laid below, or may both be laid on top.

### Fourth Embodiment

Recently, there is a demand for a thinner backlighting device 12 for the liquid crystal display 10 (e.g. a liquid crystal display 10 for in-vehicle use). The thickness of the backlighting device 12 can be reduced, for example, by formation of a predetermined specific pattern on the diffuser panel 16.

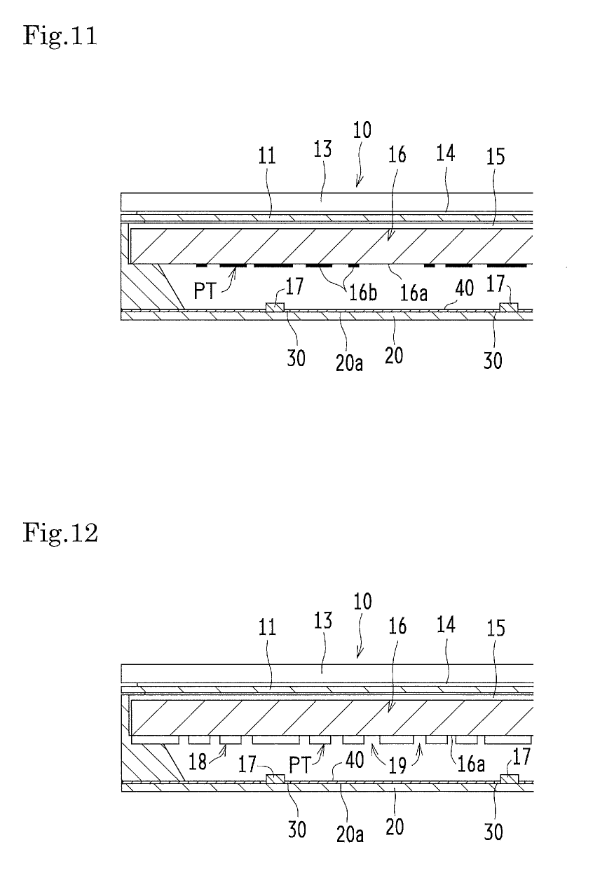

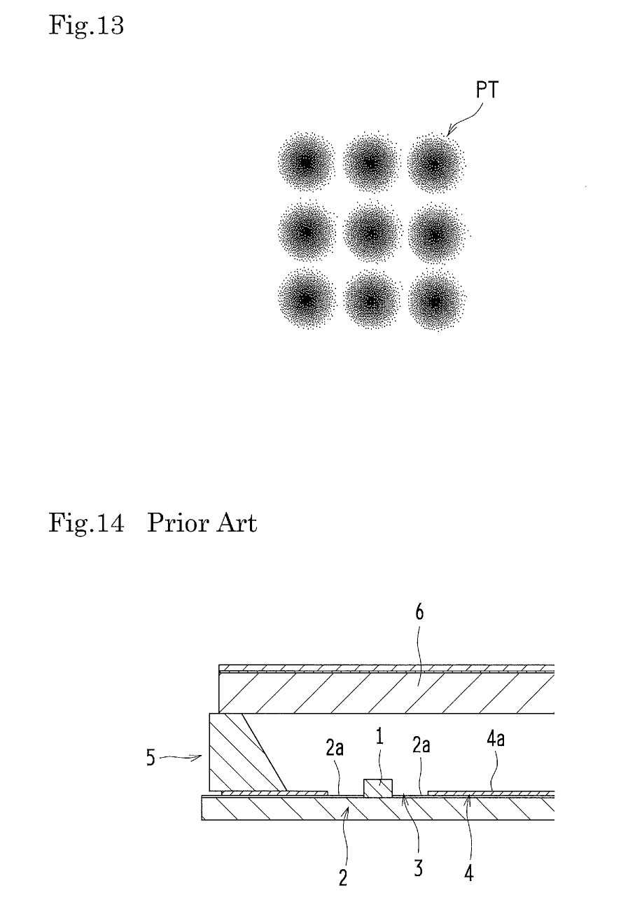

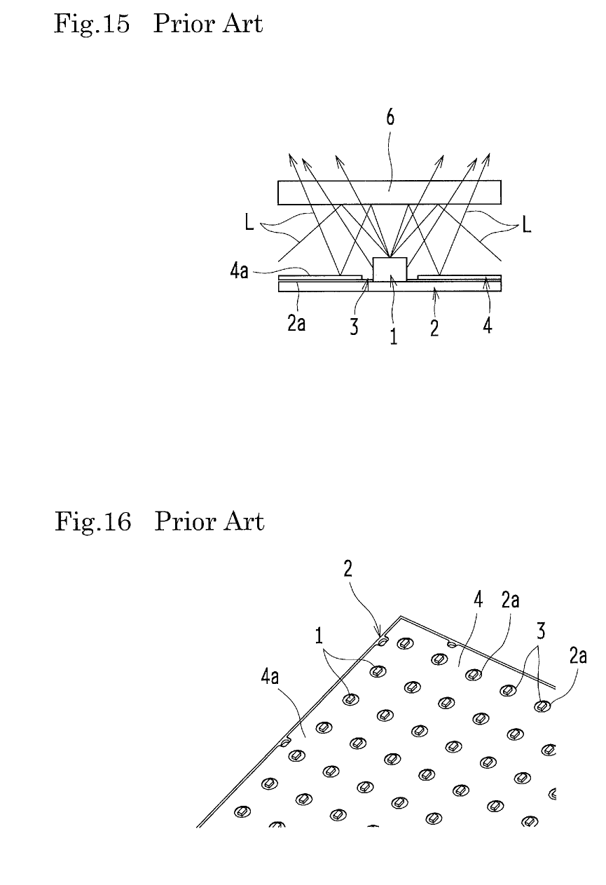

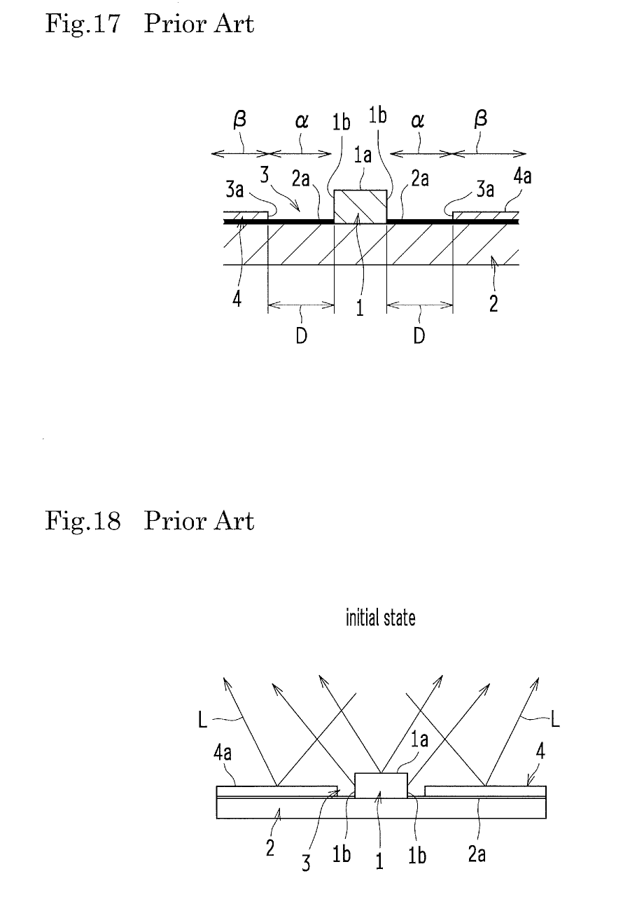

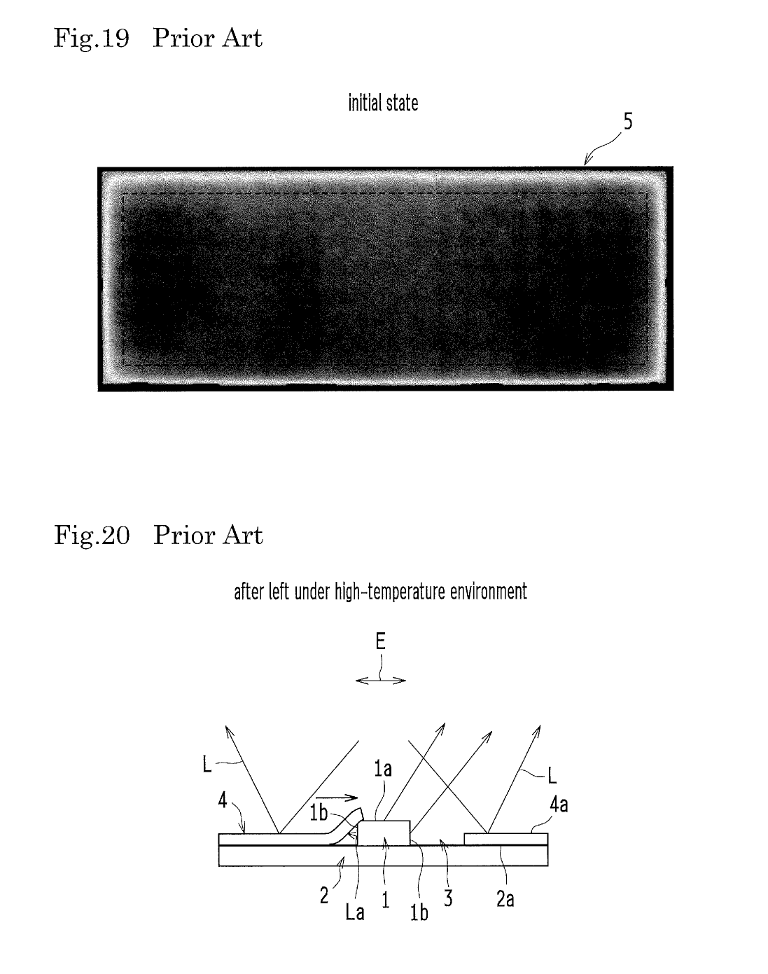

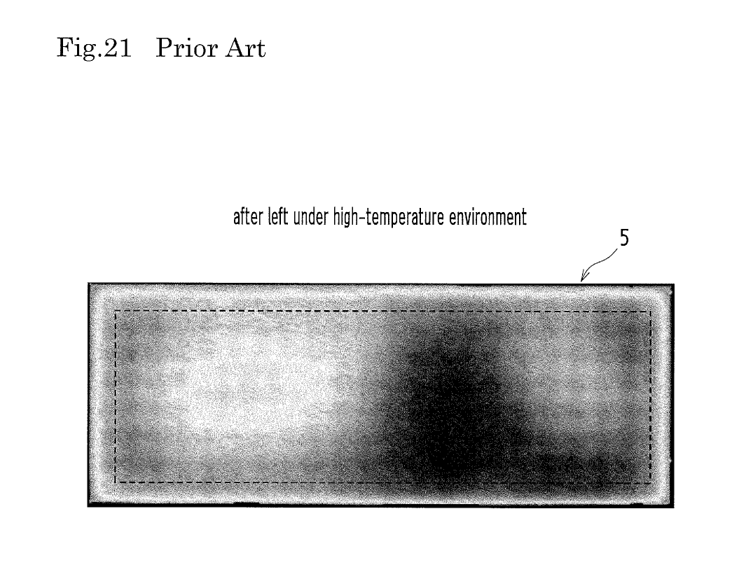

FIG. 11 is a schematic sectional view of a configuration example, in which a specific pattern PT is printed in ink on a surface 16a of the diffuser panel 16 opposed to the LED board 20. FIG. 12 is a schematic sectional view of a configuration example, in which a reflection panel 18 having apertures 19 in a specific pattern PT is provided on the surface 16a of the diffuser panel 16 opposed to the LED board 20. FIG. 13 is a schematic plan view showing an example of the specific pattern PT shown in FIGS. 11 and 12.

In this embodiment, a predetermined specific pattern is provided on the diffuser panel 16 as shown in FIGS. 11 to 13.

In the configuration shown in FIG. 11, a specific pattern PT (e.g. a dot pattern as shown in FIG. 13) is formed on the surface 16a of the diffuser panel 16 opposed to the LED board 20, by silkscreen printing using a white resist 16b (specifically, white ink). The white resist 16b may be made of the same material as the white resist 20a formed on the LED board 20. In the configuration shown in FIG. 12, a reflection panel 18 in which apertures 19 are formed in a specific pattern PT (e.g. a dot pattern as shown in FIG. 13) is attached to the surface 16a of the diffuser panel 16 opposed to the LED board 20. The reflection panel 18 may be made of the same material as the reflection sheet 40. As shown in FIG. 13, the specific pattern PT is designed to change the optical reflectance according to the luminance distribution of the LEDs 17 (depending on the distance from the light source) such that light from the LEDs 17 can be uniform. Each part of the pattern PT blocks light directly above the LEDs 17-17, repeats reflection and diffusion of light, and can thereby provide uniform illumination of light. This embodiment can make the backlighting device 12 further thinner. Having said that, the thinner backlighting device 12 raises the device temperature and makes the inside of the backlighting device 12 hotter. In this situation, the apertures 30-30 in which the first distance X is greater than the second distance Y are more effective.

The present invention should not be limited to the above-described embodiments and can be embodied and practiced in other different forms. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

What is claimed is:

1. A lighting device comprising:
a board on which a plurality of light emitting devices are arranged in a matrix; and
a reflection sheet provided on the board and having a plurality of apertures,
the apertures corresponding one-to-one to the light emitting devices,
wherein the reflection sheet is extended in a predetermined specific extending direction, and
wherein the apertures are formed such that a first distance in the extending direction between rims of the apertures and side surfaces of the corresponding light emitting devices within the apertures is greater than a second distance in an orthogonal direction that is orthogonal to the extending direction between the rims of the apertures and the side surfaces of the corresponding light emitting devices.

2. The lighting device according to claim 1,
wherein the light emitting devices are positioned at the center of the corresponding apertures, and
wherein the apertures are formed in the reflection sheet to satisfy following Formula 1,
X>Y+t/2 Formula 1
where X represents the first distance, Y represents the second distance, and t represents an amount of heat shrinkage of the reflection sheet under a predetermined specific high-temperature environment.

3. The lighting device according to claim 1,
wherein the light emitting devices have a shape elongated in a specific longitudinal direction, as seen in plan view of the board, and
wherein the light emitting devices are provided on the board such that the longitudinal direction is aligned with the extending direction.

4. The lighting device according to claim 1,
wherein the reflection sheet is divided into a plurality of pieces in the extending direction.

5. The lighting device according to claim 4,
wherein the divided reflection sheets are provided on the board, with adjacent ends of the reflection sheets being overlapped.

6. The lighting device according to claim 1, further comprising
a diffuser panel provided opposite to a mount surface of the board on which the light emitting devices are mounted,
wherein the diffuser panel has a predetermined specific pattern formed thereon.

7. The lighting device according to claim 1, further comprising:
a diffuser panel provided opposite to a mount surface of the board on which the light emitting devices are mounted; and
a reflection panel provided on a surface of the diffuser panel opposed to the board and having a predetermined specific pattern.

8. The lighting device according to claim 1,
wherein the light emitting devices emit light from light emitting surfaces thereof which are not in contact with the board and also from the side surfaces around the light emitting surfaces.

9. A display device comprising the lighting device according to claim 1.
